(19) United States
(12) Patent Application Publication
(10) Pub. No.: US 2011/0014457 A1
(43) Pub. Date: Jan. 20, 2011

(54) Graphene Layer With An Engineered Stress Supported On A Substrate

(76) Inventors: Nathaniel J Quitoriano, Pacifica, CA (US); Theodore I Kamins, Palo Alto, CA (US); Alexandre M. Bratkovski, Mountain View, CA (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/505,265

(22) Filed: Jul. 17, 2009

(51) Int. Cl. B05D 3/02; H01B 1/04; B32B 9/00; B32B 37/00; C30B 23/02

(52) U.S. Cl. 428/336; 252/502; 428/702; 427/226; 156/60; 428/697; 117/88

(57) ABSTRACT

A structure comprising a layer of graphene supported on a substrate wherein the substrate is pre-selected to have a coefficient of thermal expansion that is either matched within about 10% of that of graphene or mis-matched, thereby inducing controlled stress in the graphene layer to control electrical and/or mechanical properties of devices fabricated in the graphene layer.

### BACKGROUND ART

The present application relates generally to a structure including a graphene layer and a method for forming a graphene layer.

Graphene is the basic structural element of other graphitic materials including graphite, fullerenes, and carbon nanotubes. Graphene is formed of sp²-bonded carbon atoms that are densely packed in a honeycomb crystal lattice. Generally, graphene is in the form of one-atom-thick planar sheets. Several different approaches have been proposed to form single or multiple layers of graphene. For example, exfoliation methods have been used to form small areas of single or multiple layers of graphene. Such methods, however, generally do not enable control over the size of the crystal formed or the location of single layers. Similarly, the transfer of graphene from a large piece to a substrate by rubbing is generally not amenable to forming large, controllable regions of graphene.

Graphene is a promising material for many electronic applications. Being made of a monolayer of sp² carbon atoms, it needs to be supported by a handle wafer. For electronic purposes, this handle wafer should be effectively insulating such that the electron transport is dominated by the graphene sheet.

The properties of a graphene layer are affected by the environment of the graphene layer. In particular, stress or strain in the graphene layer can change its electrical properties. Stress or strain can change or induce a non-zero bandgap in the graphene layer; and consequently, it can also affect the carrier density, mobility of carriers, and other properties of the graphene layer. The zero bandgap half-metallic band structure is due to its D₃ₕ symmetry group. Lifting the symmetry by, for example, uniaxial deformation may induce the bandgap. The bandgap may also be induced by graphene buckling. Bi-layer graphene has a bandgap in its unstrained state, and the size of the bandgap will be strongly affected by the deformation of the sheet (via the large deformation potential of graphene). The size of the bandgap is the most important characteristic of the material that controls the carrier density, mobility, optical properties and so forth.

Placing the graphene sheet on an insulator poses a problem, however, because of mismatches in coefficients of thermal expansion. Most materials, upon cooling, shrink and so as the graphene on an insulator structure cools, the graphene sheet tends to buckle because graphene expands while the material supporting it contracts.

Usually, graphene is placed upon an insulator like SiO₂ (possibly on Si) or SiC or the like, all of which have a different coefficient of thermal expansion. Consequently, when the material cools from the formation temperature, the sheet buckles,

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1 is a side elevational view of a graphene-insulator-graphite structure, in accordance with an embodiment.

FIG. 2 is a side elevational view of a graphene-substrate structure, wherein the substrate has a negative coefficient of thermal expansion over some temperature range, in accordance with an embodiment.

FIG. 3 is a flow diagram, showing a process for forming the structures depicted in FIGS. 1 and 2, in accordance with an embodiment.

### DETAILED DESCRIPTION OF THE EMBODIMENTS

As noted above, the electrical properties of a graphene layer depend on the stress or strain in the graphene layer at the measurement temperature or during operation of a device formed in the graphene layer. The stress and strain can be controlled by utilizing the different thermal coefficients of expansion of a graphene layer and the supporting substrate. Thus, an engineered or controlled stress induced in the graphene layer may be used to control electrical properties of devices fabricated in the graphene layer.

If the graphene layer is stress-free at the temperature at which it is formed or attached to the substrate, then the stress and strain at the measurement or device operating temperature depend on the difference in thermal coefficient of expansion of the graphene layer and the substrate and the temperature difference between the formation/attachment temperature and the measurement/operating temperature. Most materials, upon cooling, shrink and so as the graphene on an insulator structure cools, the stress develops in the graphene sheet; in the extreme state, the graphene layer tends to buckle because it expands, due to its negative coefficient of thermal expansion (CTE) while the material supporting it contracts. In accordance with the teachings herein, a stress-free layer can be obtained, in one embodiment, by using a substrate with a coefficient of thermal expansion similar to that of graphene. In an embodiment, a graphite substrate on top of which is a thin layer of insulator, may be used. This structure provides both an insulating layer upon which the graphene sheet is attached and a material with a matched CTE. This is the case because with a relatively thick substrate and a relatively thin insulator film, the mechanical properties, i.e. the coefficient of thermal expansion, of the substrate dominates, provided that misfit dislocations do not form. In other embodiments, the graphene may be formed directly on an insulating substrate.

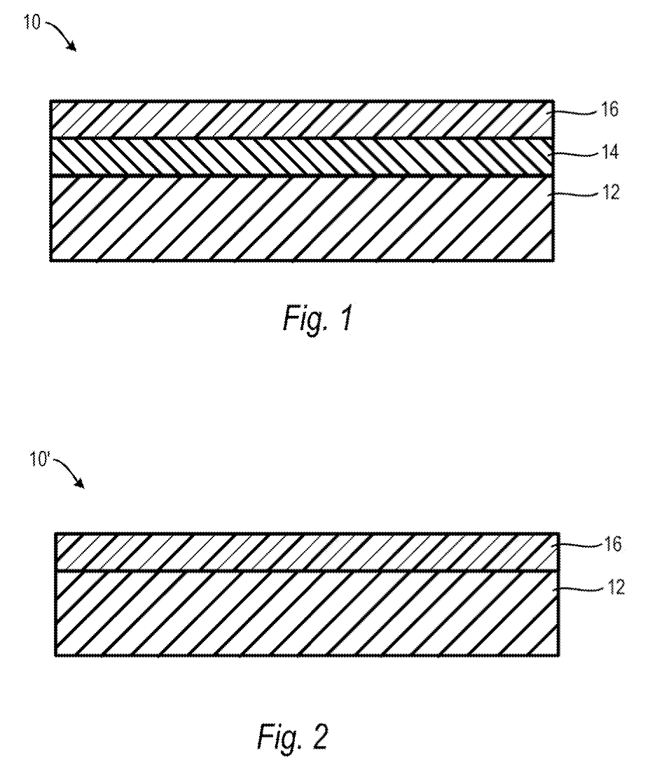

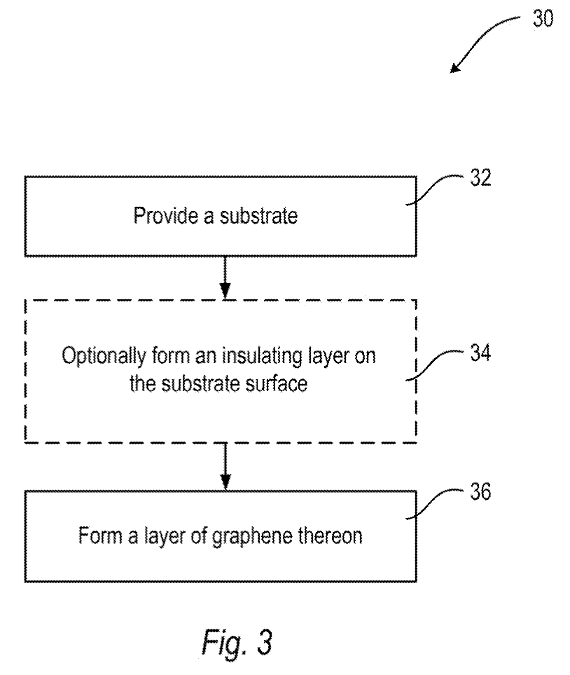

In the former case (graphite substrate), the structure is composed of a graphite substrate, a thin insulating layer and a graphene sheet on top. Specifically, a graphene-insulator-graphite structure 10 is depicted in FIG. 1 comprising the graphite substrate 12, the thin insulating layer 14 on the substrate, and the graphene sheet 16 on the thin insulating layer.

Graphite has a negative CTE to about 400° C. with small coefficient of thermal expansion above this temperature.

In the graphene-insulator-graphite structure 10, the thickness of the insulating layer should be thick enough to provide electrical insulation from the underlying graphite substrate 12, but thin enough to permit the bulk CTE of the graphite substrate to dominate. The thickness will accordingly depend on the composition of the insulating layer. Materials comprising the insulating layer may include relatively high temperature metal or semiconductor oxides, nitrides, oxynitrides, carbides, and the like. In particular, examples may be selected from the group consisting of SiC, SiO₂Si₃N₄, SiOₓN_{y}, and Al₂O₃. In some embodiments, the thickness of the insulating layer 14 may range from about 2 to 100 nm on a graphite substrate.

The thickness of the graphene layer 16 may be less than 10 atomic layers in some embodiments, and less than 3 atomic layers in other embodiments. In other embodiments, the thickness of the graphene layer 16 is a single atomic layer.

In the latter case (insulating substrate), which is a more general case, a structure 10′, shown in FIG. 2, may comprise a graphene layer 16 directly on a substrate 12 comprising a negative coefficient of thermal expansion material. The negative CTE material itself is insulating, thus eliminating the need for an insulating layer 14, although a thin insulating layer analogous to layer 14 in FIG. 1 may be provided in some embodiments.

In an embodiment, the CTE is relatively similar over a range of about 750 to 1200° C. for CVD growth of graphene sheets. In another embodiment, the CTE is relatively similar over a range of about 1200 to 1700° C. for the sublimation of SiC to form graphene.

In some embodiments, by mixing a composite material whose components have different CTEs, one can engineer the CTE of the substrate to span the range of the CTE values between component A and component B if, in one embodiment, the composite was made of two components. In this embodiment, if component A has CTE “a” and component B has CTE “b”, then a composite material made from A and B may have any CTE between “a” and “b”. In this manner, the CTE may be engineered and, as such, the strain of the graphene sheet may be engineered as well to be tensile, unstrained or compressive.

In an embodiment, for a material that sticks well to graphite and has CTE>0, one may grow, deposit, bond graphite or graphene on top of this layer and adjust the layer thickness to tailor the CTE of the stack. This material that sticks well to the graphite or graphene should also be insulating such that the electrical conduction is dominated by that of the graphite or graphene. In another embodiment, the graphite or graphene layer may not be planar and because therefore the electronic properties of the graphite or graphene layer will change and there will be a bandgap.

There are a number of negative CTE materials in which the CTE is negative over a temperature range that includes temperatures above room temperature. A negative CTE at elevated temperatures permits fabrication of the graphene layer 16 at elevated temperatures and cooling to room temperature, without substantial buckling of the graphene layer. In some embodiments, there may be some buckling, but it may be rather minor and have little impact on the graphene properties. For example, in some embodiments, such buckling may be about 5 to 30 Å over ˜100 nm.

Cubic zirconium tungstate (ZrW₂O₈) is one example of a material suitably employed as the substrate 12. This compound contracts continuously over a temperature range of 0.3 to 1050 K (at higher temperatures, the material decomposes). Other materials that exhibit this behavior include: other members of the AM₂O₈ family of materials (where A=Zr or Hf, M=Mo or W) and ZrV₂O₇. Other examples of materials having controllable negative thermal expansion include A₂(MO₄)₃, such as Sc₂(MO₄)₃.

Quartz and a number of zeolites also show negative CTE over certain temperature ranges. In addition to AM₂O₈ and A₂(MO₄)₃, additional examples include members of the families of MO₂, AM₂O₇, A₂M₃O₁₂, AMO₅, and AO₃, where in the foregoing families, A is an octahedral cation, M is a tetrahedral cation, and the oxygen coordination is two.

In some embodiments, it may be desirable to include the insulating layer 14, notwithstanding the foregoing. In such cases, the thickness of the insulating layer 14 is somewhat relative to the CTE of the underlying bulk substrate 12. The insulating layer 14, in some embodiments, may be thin compared to that of the bulk substrate 12 underneath so that the coefficient of thermal expansion of the bulk substrate dominates the expansion/contraction of the whole device 10.

In other embodiments, it is desired to induce a controlled stress into the graphene layer to modify the electrical properties of the graphene layer. The controlled stress can be induced by proper choice of the substrate material because the stress is dominated by the thick substrate, and only modified slightly by a thin insulating layer between the graphene layer and the substrate. As stated above, materials with both positive and negative coefficients of thermal expansion are readily available so that the substrate can be selected to induce the desired stress in the graphene layer at the measurement/operating temperature. To obtain more flexibility, alloys containing two or more different materials can be formed to adjust the coefficient of thermal expansion to the correct value to induce the desired stress in the graphene layer.

It should be noted that the coefficient of thermal expansion of a material is not constant over an extended temperature range. The stress in a film/substrate structure, therefore, depends on the difference in coefficients of thermal expansion of the two materials summed (integrated) over the temperatures between the formation/attachment temperature and the measurement/operating temperature. For simplicity of discussion only, the coefficient of thermal expansion is taken to be constant over the relevant temperature range with the understanding that the proper design of the structure must consider the temperature variation of the coefficients of thermal expansion of the graphene layer and the substrate.

FIG, 3 depicts a general scheme 30 for fabricating the graphene layer 16 to form the structure 10, 101. In step 32, a substrate 12 may be provided. If the substrate 12 is graphite or another material with a significant conductivity, then optional step 34 would be employed, namely, forming an insulating layer 14 on the substrate surface. Graphene 16 may then be formed on the insulating layer 14 (if the substrate 12 is graphite or another conductor) or formed directly on the substrate if the substrate is one of the metal or semiconductor oxides or another insulator described above.

The fabrication of the structure 10, 10′ may be accomplished in several ways including:
1. Epitaxial growth of graphene 16 on the insulating layer 12. In this process, the graphene sheet may be grown via a chemical vapor deposition process at elevated temperatures. In some embodiments, a metal seed layer is used, such as Ni or Fe, to help crack the precursor gas, in one embodiment CH₄, into its constituent parts to grow a graphene sheet. (The insulating layer may be made single crystalline, at least over the desired area of a device or chip, by a bond and transfer process.)
2. Sublimation of SiC. Graphene sheets are known to be made by the sublimation of Si from SIC in ultra-high vacuum (UHV) conditions at high temperatures. In this embodiment, at these high temperatures, Si sublimates, leaving behind carbon on the surface which bonds with other carbon atoms to form graphene sheets. The SiC can be single crystalline and can help in the registry of the graphene sheets. Single crystalline SiC may be able to be grown directly on single crystalline graphite (low mosaicity HOPG) or may be transferred to the graphite using a bonding and transfer process.
3. Another possible method may be to implant, say Si, into a conducting substrate, say graphite, to form a buried insulator of a material like SiC. In this embodiment, this is analogous to the SIMOX (Separation by Implantation of Oxygen) process, which implants oxygen into a Si wafer at an elevated temperature followed by further high-temperature heat treatment,
4. If a substrate other than graphite is used, the graphene layer may be attached using well-known bonding techniques. Some of these techniques rely on van der Waal's forces, which may be adequate because the graphene layer is thin, or stronger forces.

In the epitaxial growth of graphene on the insulating layer 12 (first procedure above) and the transfer to a different substrate (last procedure above), the development of layer transfer for integration of dissimilar materials (bond and transfer process) relies greatly on the “paste-and-cut” approach. This approach consists of a film grown on one substrate (the donor substrate) to a receptor substrate, followed by the delamination of the film from the handle substrate. In some applications, the original surface of the transferred layer must be the exposed surface after the layer is transferred to the receptor substrate.

A two-stage process known as “double transfer” may be employed in some embodiments. In double transfer, the film is first transferred to a temporary receptor or “handle” substrate using a temporary bond, and then the film is bonded to the final substrate (receptor) with a permanent bond. Delamination of the handle substrate completes the transfer process. For successful transfer, the bond strength at the interface between the temporary bond and the handle substrate must be stronger than the bond strength at the interface between the film and the donor substrate during the “cutting” process. In the second stage of double transfer, however, the bond strength of the interface between the film and the handle wafer must be lower than the bond strength at the interface between the film and the receptor substrate. Based on these inequalities, it is clear that choice of the temporary bonding material and engineering of the bonding strength are essential to the success of the double-transfer process.

The advantages of the structure 10, 10′ is that this structure provides a graphene sheet with a sturdy, insulating substrate with matched coefficient of thermal expansion or mismatched coefficients of thermal expansion chosen to achieve a desired or “engineered” stress in the graphene layer, which enables devices subsequently fabricated in the graphene layer to have optimized electrical properties.

What is claimed is:

1. A structure comprising a layer of graphene supported on a substrate, wherein the substrate is pre-selected to have a coefficient of thermal expansion that is either matched within about 10% of that of graphene or mis-matched, thereby inducing controlled stress in the graphene layer to control electrical and/or mechanical properties of devices fabricated in the graphene layer.

2. The structure of claim 1 wherein the coefficient of thermal expansion of the substrate is matched to within about 10% of that of graphene.

3. The structure of claim 1 wherein the substrate includes an insulating layer on the surface, the insulating layer having a thickness compared to the substrate such that the coefficient of thermal expansion of the substrate dominates.

4. The structure of claim 1 wherein the substrate comprises graphite and the insulating layer comprises a metal or semiconductor oxide, nitride, oxynitride, or carbide.

5. The structure of claim 1 wherein the insulating layer has a thickness ranging from about 2 to 100 nm.

6. The structure of claim 1 wherein the substrate comprises a material selected from the group consisting of AM₂O₈, A₂(MO₄)₃, MO₂, AM₂O₇, A₂M₃O₁₂, AMO₅, and AO₃ where A is an octahedral cation, M is a tetrahedral cation, and the oxygen coordination is two, quartz, and zeolites.

7. The structure of claim 6 wherein the substrate comprises a material selected from the group consisting of ZrW₂O₈, ZrV₂O₇, and SC₂(MO₄)₃.

8. The structure of claim 1 wherein the layer of graphene has a thickness of less than 10 atomic layers.

9. The structure of claim 1 wherein the coefficient of thermal expansion of the substrate is controllably mis-matched to that of graphene.

10. A method of making a structure comprising a layer of graphene supported on a substrate, wherein the substrate is pre-selected to have a coefficient of thermal expansion that is either matched within about 10% of that of graphene or mismatched, thereby inducing controlled stress in the graphene layer to control electrical and/or mechanical properties of devices fabricated in the graphene layer, the method comprising:
providing the substrate; and
forming the layer of graphene thereon.

11. The method of claim 10 wherein the coefficient of thermal expansion of the substrate is matched to within about 10% of that of graphene.

12. The method of claim 11 wherein the substrate includes an insulating layer on the surface, the insulating layer having a thickness compared to the substrate that is thin enough to avoid having an appreciable effect on the coefficient of thermal expansion of the structure.

13. The method of claim 12 wherein the substrate comprises graphite and the insulating layer comprises metal or semiconductor oxides, nitrides, oxynitrides, or carbides.

14. The method of claim 12 wherein the insulating layer has a thickness ranging from about 2 to 100 nm on a graphite substrate.

15. The method of claim 12 wherein graphene is epitaxially grown on the insulating layer.

16. The method of claim 12 wherein the layer of graphene is formed by disposing a layer of SiC on the substrate and sublimation of Si from the SiC to leave graphene.

17. The method of claim 16 wherein the layer of SiC is either grown on a single crystalline graphite substrate or transferred to the graphite substrate using a bonding and transfer process.

18. The method of claim 10 wherein silicon is implanted into graphite to form a SiC insulator underneath carbon atoms which could form a graphene sheet.

19. The method of claim 10 wherein the layer of graphene is formed to a thickness of less than 10 atomic layers.

20. A method of controlling stress in a graphene layer supported on a substrate having a coefficient of thermal, the method comprising:
providing a substrate having either a positive coefficient of thermal expansion or a negative coefficient of thermal expansion over a temperature range, at least a portion of which is above room temperature; and
forming a layer of graphene disposed on a surface of the substrate, whereby controlled stress induced in the graphene layer controls electrical properties and/or mechanical properties of devices fabricated in the graphene layer.
